(19) United States
(12) Patent Application Publication
(10) Pub. No.: US 2009/0305489 A1
(43) Pub. Date: Dec. 10, 2009

(54) MULTILAYER ELECTROSTATIC CHUCK WAFER PLATEN

(76) Inventor: Roger B. Fish, Bedford, MA (US)

Correspondence Address: Nields, Lemack & Frame, LLC, 176 E. MAIN STREET, SUITE 5, WESTBOROUGH, MA, 01581, US

(21) Appl. No.: 12/142,922

(22) Filed: Jun. 20, 2008

Related U.S. Application Data
(60) Provisional application No. 61/059,140, filed on Jun. 5, 2008.

(51) Int. Cl. H01L 21/265; H01L 21/683; H01R 43/00

(52) U.S. Cl. 438/514; 361/234; 29/825; 257/E21.334

(57) ABSTRACT

This layered assembly utilizes two-piece construction, with an electrically nonconductive layer and a thermally conductive layer. Rather than using metal, the thermally conductive layer is made from a composite material, having both metal and a CTE modifying agent. This composite material may a coefficient of thermal expansion close to or identical to that of the nonconductive layer, thereby eliminating many of the drawbacks of the prior art. In one embodiment, the composite material is a mixture of aluminum and carbon (or graphite) fiber. In a further embodiment, one or more fluid conduits are placed in the mold before the layer is cast. These conduits serve as the fluid passageways in the electrostatic chuck. In another embodiment, the composite material is a mixture of a semiconductor material, such as silicon, and aluminum where the conduits are formed by machining and bonding.

This application claims priority of U.S. Provisional Patent Application Ser. No. 61/059,140, filed Jun. 5, 2008, the disclosure of which is incorporated herein by reference.

### BACKGROUND OF THE INVENTION

Ion implanters are commonly used in the production of semiconductor wafers. An ion source is used to create an ion beam, which is then directed toward the wafer. As the ions strike the wafer, they dope a particular region of the wafer. The configuration of doped regions defines their functionality, and through the use of conductive interconnects, these wafers can be transformed into complex circuits.

A block diagram of a representative ion implanter 100 is shown in FIG. 1. An ion source 110 generates ions of a desired species. In some embodiments, these species are atomic ions, which may be best suited for high implant energies. In other embodiments, these species are molecular ions, which may be better suited for low implant energies. These ions are formed into a beam, which then passes through a source filter 120. The source filter is preferably located near the ion source. The ions within the beam are accelerated/decelerated in column 130 to the desired energy level. A mass analyzer magnet 140, having an aperture 145, is used to remove unwanted components from the ion beam, resulting in an ion beam 150 having the desired energy and mass characteristics passing through resolving aperture 145.

In certain embodiments, the ion beam 150 is a spot beam. In this scenario, the ion beam passes through a scanner 160, which can be either an electrostatic or magnetic scanner, which deflects the ion beam 150 to produce a scanned beam 155-157. In certain embodiments, the scanner 160 comprises separated scan plates in communication with a scan generator. The scan generator creates a scan voltage waveform, such as a sine, sawtooth or triangle waveform having amplitude and frequency components, which is applied to the scan plates. In a preferred embodiment, the scanning waveform is typically very close to being a triangle wave (constant slope), so as to leave the scanned beam at every position for nearly the same amount of time. Deviations from the triangle are used to make the beam uniform. The resultant electric field causes the ion beam to diverge as shown in FIG. 1.

In an alternate embodiment, the ion beam 150 is a ribbon beam. In such an embodiment, there is no need for a scanner, so the ribbon beam is already properly shaped.

An angle corrector 170 is adapted to deflect the divergent ion beamlets 155-157 into a set of beamlets having substantially parallel trajectories. Preferably, the angle corrector 170 comprises a magnet coil and magnetic pole pieces that are spaced apart to form a gap, through which the ion beamlets pass. The coil is energized so as to create a magnetic field within the gap, which deflects the ion beamlets in accordance with the strength and direction of the applied magnetic field. The magnetic field is adjusted by varying the current through the magnet coil. Alternatively, other structures, such as parallelizing lenses, can also be utilized to perform this function.

Following the angle corrector 170, the scanned beam is targeted toward the workpiece 175. The workpiece is attached to a workpiece support. The workpiece support provides a variety of degrees of movement.

The workpiece support is used to both hold the wafer in position, and to orient the wafer so as to be properly implanted by the ion beam. To effectively hold the wafer in place, most workpiece supports typically use electrostatic force. By creating a strong electrostatic force on the upper side of the support, also known as the electrostatic chuck, the wafer can be held in place without any mechanical fastening devices. This minimizes contamination and also improves cycle time, since the wafer does not need to be unfastened after it has been implanted. These chucks typically use one of two types of force to hold the wafer in place: coulombic or Johnson-Rahbeck force.

As seen in FIG. 2, this chuck 200 traditionally consists of two layers. The first, or top, layer 210, which contacts the wafer, is made of an electrically insulating or semiconducting material, such as alumina, since it must produce the electrostatic field without creating a short circuit. Methods of creating this electrostatic field are known to those skilled in the art and will not be described herein. For those embodiments using coulombic force, the resistivity of the top layer, which is typically formed using crystalline and amorphous dielectric materials, is typically greater than 10¹⁴ Ω-cm. For those embodiments utilizing Johnsen-Rahbeck force, the volume resistivity of the top layer, which is formed from a semiconducting material, is typically in the range of 10¹⁰ to 10¹² Ω-cm. The term “non-conductive” will be used to describe materials in either of these ranges, and suitable for creating either type of force. The coulombic force can be generated by an alternating voltage (AC) or by a constant voltage (DC) supply.

The second, or bottom, layer 220 is preferably made from metal or metal alloy with high thermal conductivity to maintain the overall temperature of the chuck within an acceptable range. In many applications, aluminum is used for this bottom layer. In some embodiments, this bottom layer has two separate aluminum portions. The lower portion is thick and contains fluid passageways. Typically, the top surface of an aluminum block is machined to introduce channels 230 through which coolant is passed. The coolant can be any suitable fluid, including water and de-ionized water. A much thinner second aluminum plate is formed to act as a lid for this thicker aluminum block, providing a cover for these machined passageways. These two aluminum portions are bonded together to form the thermally conductive lower layer of the electrostatic chuck. This layer and the previously described electrically non-conductive layer are then mechanically affixed together, such as by epoxy, brazing material or other adhesive technique 240.

While this configuration has been used for some time, there are a number of drawbacks associated with it. First of all, the aluminum in the bottom layer tends to corrode due to the interaction with the coolant being passed through it. Second, the coefficients of thermal expansion (CTE) of the top and bottom layers of the chuck are not the same. Alumina, Al₂O₃, has a CTE of approximately 5.5 at 25° C., while aluminum has a CTE of about 23. Furthermore, alumina's CTE also varies from 0.6 to 8.0 over the range of ±200° C. This leads to issues when the temperature of the chuck deviates from that used when the layers were assembled.

For example, assume the aluminum and the alumina of the chuck are affixed to each other using an adhesive, such as epoxy, at room temperature. At this temperature, the two layers each have a certain volume and surface area. However, as the temperature of the chuck deviates from room temperature, each expands and contracts at a different rate, with the aluminum layer expanding and contracting at a much faster rate than the alumina layer. This places the interface between the layers under great stress.

As the temperature increases, the aluminum or metal material expands at a rate roughly three times that of the alumina or other nonconductive material. As a result, the aluminum layer 220 expands more than the alumina layer 210, causing the chuck to bow inwardly, creating a concave work surface 250, as shown in FIG. 3. Conversely, as the temperature decreases, the aluminum 220 contracts at a much faster rate than that of the alumina 210. As a result, the chuck bows outwardly, creating a convex work surface 250 as shown in FIG. 4.

This tension between the two layers usually causes the adhesive material or epoxy to break over time, rendering the chuck useless. In other words, the thermal stress created in the bonding layer is greater than the maximum strength of that bonding material. In other cases, the flexing causes the brittle nonconductive material used in the top layer to shatter, again destroying the chuck.

As a result, most electrostatic chucks have very narrow operating ranges with respect to temperature. This obviously limits the usefulness of these chucks. Further compounding this issue, new implantation techniques using temperatures significantly different than ambient are being investigated with great promise. The extreme temperature ranges associated with these new implantation techniques will exacerbate the CTE discontinuity issue described above.

Consequently, a layered assembly that can tolerate a wide range of temperatures without any ill effects would be advantageous. In addition, an electrostatic chuck that can utilize a variety of coolants without corroding is also desirable.

### SUMMARY OF THE INVENTION

The problems of the prior art are overcome by the layered assembly described in the present disclosure. This assembly utilizes multiple-piece construction, including an electrically non-conductive layer and a thermally conductive layer. Rather than using metal, the thermally conductive layer is made from a composite material, having both metal and a CTE modifying agent. This composite material may have a coefficient of thermal expansion close to or identical to that of the non-conductive layer, thereby eliminating many of the drawbacks of the prior art.

In one embodiment, the composite material is a mixture of aluminum and carbon (or graphite) fiber. This material has many of the properties of metal, allowing it to be cast in much the same manner that the aluminum layers are manufactured today. In a further embodiment, one or more fluid conduits are placed in the mold before the layer is cast. These conduits serve as the fluid passageways in the electrostatic chuck.

In another embodiment, the composite material is a mixture of a semiconductor material, such as silicon, and aluminum. Silicon has a CTE of about 2.3, which is much lower than alumina. The aluminum concentration increases the thermal conductivity of the material, as well as its CTE. However, since this material is mostly silicon, it cannot be machined like metal. Rather, its manufacturing process is akin to those used for ceramics.

### BRIEF DESCRIPTION OF FIGURES

FIG. 1 represents a traditional ion implanter;

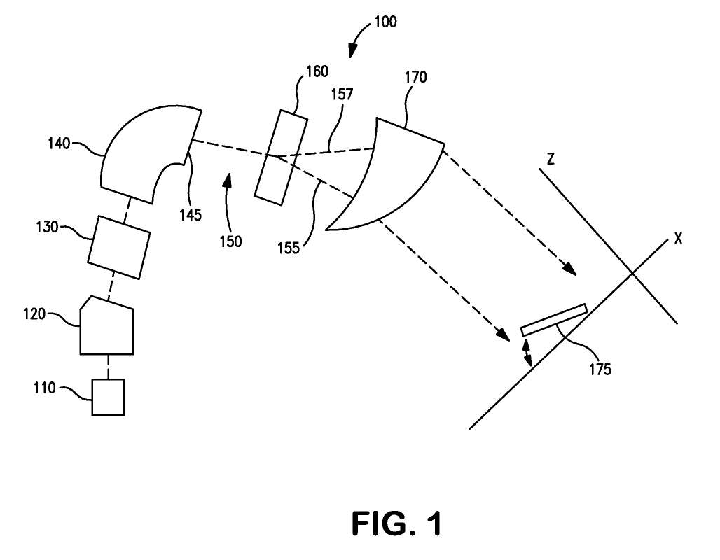

FIG. 2 represents a electrostatic chuck of the prior art;

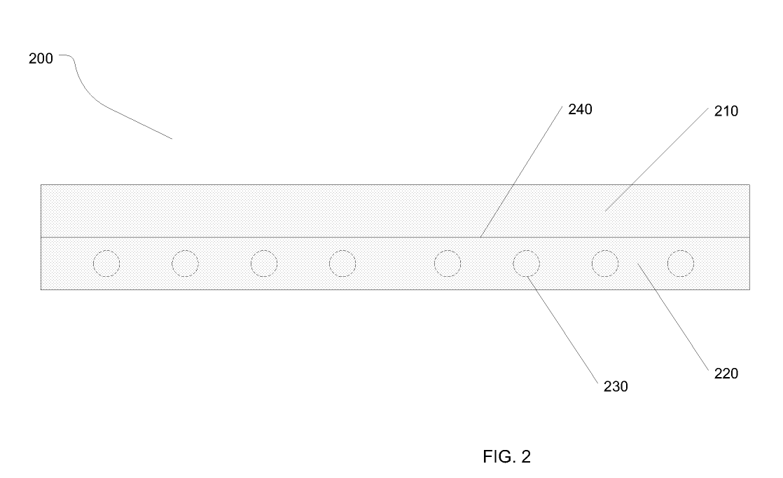

FIG. 3 represents the chuck of FIG. 2 at an elevated temperature;

FIG. 4 represents the chuck of FIG. 2 at a low temperature;

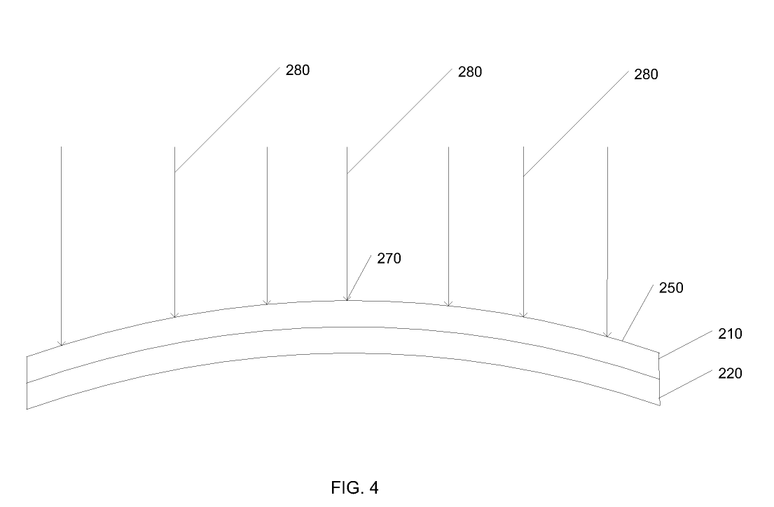

FIG. 5 represents a first embodiment of the chuck described in this disclosure;

FIG. 6 represents an expanded view of the chuck of FIG. 5; and

FIG. 7 represents the terminals of the conduit used in FIG. 6.

### DETAILED DESCRIPTION OF THE INVENTION

As described above, electrostatic chucks (ESCs) include two parts, an electrically non-conductive top layer, and a thermally conductive bottom layer. To manufacture these layered assemblies, insulators or semiconductors, such as Alumina (aluminum oxide, Al₂O₃) and the like, are commonly used to form the top layer. The thermally conductive layer is preferably manufactured from a metal, such as aluminum. As stated above, the coefficients of thermal expansion (CTE) for these two layers are very different, which causes significant problems if the temperature of the ESC is outside its narrow operating range. Conventional ESCs are limited in their operating range by the stresses generated in the interface between the different layers, due to the difference is their coefficients of thermal expansion. For example, a conventional ESC, which is formed by bonding an aluminum base to an alumina insulator with an epoxy has a working temperature range of −20° C. to +60° C. Stress in the bonding layer causes separation of the top and bottom layers at temperatures outside this range. Stronger epoxies or higher strength bonding techniques cannot be used to remedy this failure. If the same ESC is formed using a stronger bonding agent, at a temperature significantly below the manufacturing temperature, such as −80° C., the alumina layer will fracture due to stresses that exceed its ultimate strength.

To alleviate these problems, the bottom layer is manufactured from a composite material. By combining a metal, such as aluminum, with a CTE modifying agent, such as carbon, silicon or silicon carbide, the coefficient of thermal expansion of the resulting composite can manipulated so as to match that of the top layer, such as to within 50% or better. By matching the CTE of the two layers, the stresses caused by thermal expansion can be maintained below the maximum strength of the bonding material, over a wider temperature range, such as ±100° C. or more. In addition, the use of a metal in the composite allows the bottom layer to retain most of its thermal conductivity and thermal capacitance. Thus, any composite material having reasonable thermal properties and a CTE matched to the top layer can be used.

The amount of CTE modifying agent controls how closely the CTE of the bottom layer is matched to the top layer. One factor that can be used to determine the amount of CTE modifying agent to use, and thus the final CTE of the bottom composite layer, is the desired operating temperature range of the layered assembly. In certain embodiments, the CTE's of the top and bottom layers are matched to within about 50% and have an operating range of ±200° C. or more. In other embodiments, these are matched to within about 25% and have an operating range of ±250° C. or more. In other embodiments, these are matched to within about 10% and have an operating range of ±270° C. Finally, embodiments in which the CTEs are within a factor of 2 (i.e. ±100%) are also contemplated and yield an operating temperature of ±150° C. As is apparent from the foregoing, the term “match”, “matching” or “matched” as used herein is not limited to an exact correspondence in CTE's.

The relationship between the CTEs of the two layers determines the assembly's operating temperature range. As the CTEs diverge, the operating temperature range shrinks. Conversely, as the CTEs approach one another, the operating range increases. Through computer simulation and other tools, those of ordinary skill in the art can determine the required relationship between the CTE of the top layer and the bottom layer to insure the desired operating range. Furthermore, the values described above assume that the failure mode is not related to the bonding material. As mentioned above, high strength bonding materials and techniques can be used so that the bond between layers does not fail. In these scenarios, the operating temperature range is therefore determined by the top layer's strength in tension, as it and the bottom layer expand or contract at different rates.

In one embodiment, the bottom layer is comprised of a composite material made from silicon and aluminum, where about 70% of the final material is silicon. One such material is available from Sandvik Osprey, Ltd. and uses a plasma spray technique to create the composite material. In this embodiment, the bottom layer is formed in two pieces, as is done in the prior art. The top surface of the lower portion is machined to introduce the passageways needed for the fluid coolant. The upper portion serves primarily as a lid, which is bonded to the top surface of the lower portion to create the bottom layer. This assembled bottom layer is then affixed to the upper layer, such as by epoxy. While the disclosure specifically enumerates composite materials from Sandvik Osprey, Ltd., the ESC is not limited to only products from this vendor. Any composite material displaying the thermal conductivity and CTE properties required can be used. For example, composite materials from CPS Technologies Corp. and 3M Aluminum Matrix Composites are also within the scope of the disclosure.

In a second embodiment, a metal matrix cast composite is used to create the bottom layer. In this embodiment, graphite or carbon fiber is placed within a casting. Molten aluminum is then added to the mold, filling the volume not occupied by the fibers. The fibers are oriented so as to constrain the expansion of the aluminum layer along its major axes (i.e. the axes parallel to the surface which is to be bonded to the top layer). Thus, this aluminum composite shares a coefficient of thermal expansion very similar to that of alumina. The metal matrix described above is available from Metal Matrix Cast Composites, LLC located in Waltham, Mass.

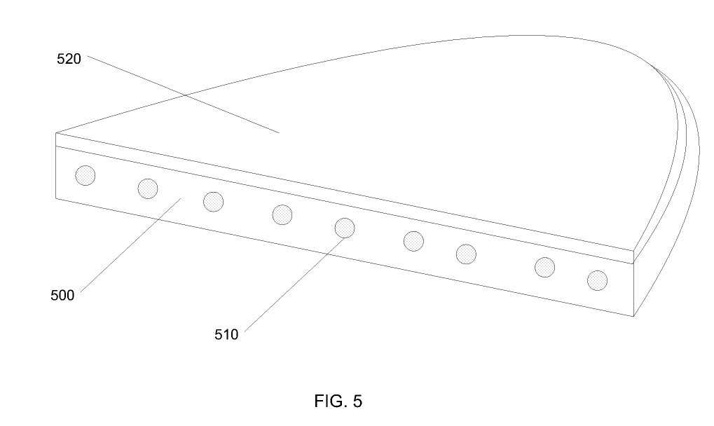

A further enhancement to this embodiment is shown in FIG. 5. In this scenario, a fluid conduit 510 is molded into the bottom layer 500 during the casting process. In operation, a conduit 510 made of a material having a higher melting point than the casting temperature, such as stainless steel, INVAR or molybdenum, is used. Typical casting temperatures are roughly 750° C. Other materials having a melting point above the casting temperature are also within the scope of the disclosure. The conduit is placed in the mold with the carbon or graphite fibers. Molten aluminum is then injected at high pressure into the mold to create the bottom layer 500. The bottom layer 500 is then affixed to the top layer 520.

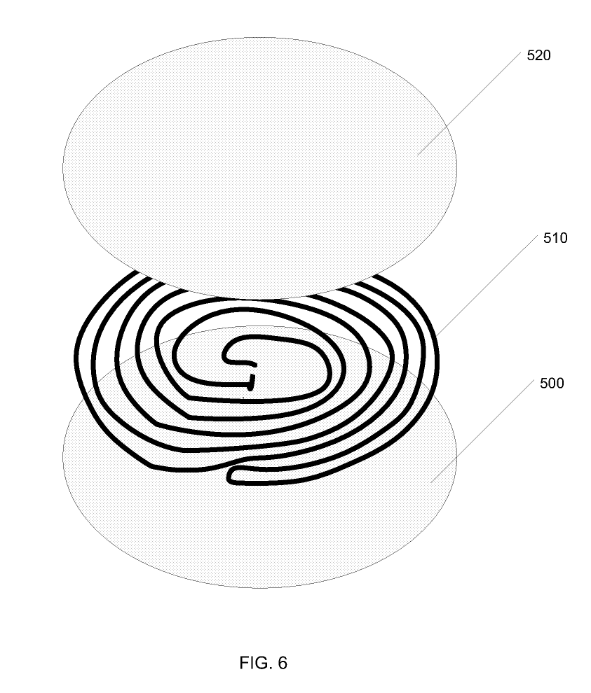

FIG. 6 shows an expanded view of the platen of FIG. 5. The conduit 510 in this example has a single inlet 540 and outlet 550 and is configured in a counterflowing pattern. However, the disclosure also contemplates other patterns. Similarly, more than one conduit can be placed within the casting to improve the temperature uniformity and regulation. Multiple conduits also allow different heating and/or cooling fluids to be used concurrently.

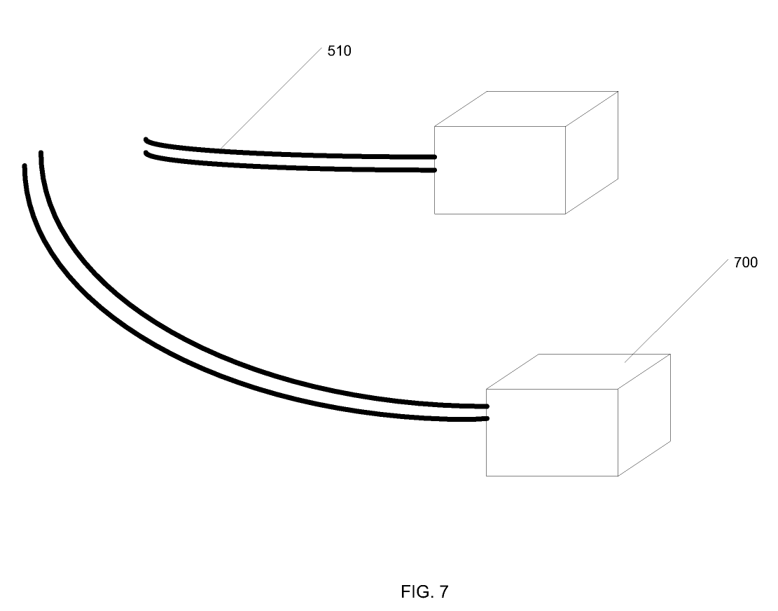

The conduit 510 is created with sealed ends, each preferably terminating in a small junction box 700, as shown in FIG. 7. The junction box is large enough so that after casting, a hole can be drilled through the composite material and into the junction box, so as to allow access to the conduit from the exterior of the bottom layer. A tool, such as a drill, is then used to make a hole in the lower surface of the bottom layer and to break open this junction box, thereby allowing fluid communication with the external environment. This process is repeated for both the inlet and outlet of the conduit, for each conduit molded into the bottom layer. The openings are created on the lower surface of the bottom layer. By incorporating these fluid conduits inside the bottom layer, the coolant is isolated from the aluminum, which eliminates the possibility of corrosion, which is commonplace in current systems.

In a second embodiment, the junction boxes are exposed on the surface of the casting. These are then machined into mating surfaces for the fluid connections.

External conduits, such as stainless steel tubes can then be attached to these openings, thereby creating a sealed fluid path through the bottom layer. As described before, fluids such as water, de-ionized water, nitrogen gas, helium gas, or industrial coolants and refrigerants are commonly used.

While many ion implantation systems operate at or near room temperature, there is currently investigation into cryogenic implantation, where the wafer is kept at temperatures between −40° C. and −200° C. In this scenario, the layered assembly of the present disclosure can be advantageously used. As described above, since the CTE of the top layer of alumina and the bottom layer of aluminum composite are matched, there is little risk of damage due to thermal contraction. Additionally, the fluid conduit can be used to pass a refrigerant, such as liquid nitrogen, gaseous nitrogen or other suitable fluids, to keep the wafer at the desired temperature.

In another cryogenic embodiment, the platen described above is kept at the desired temperature by periodically contacting it with a sufficiently cold substrate. In other words, the platen is used for one or more implantations. These implantations cause the temperature of the platen to increase. To counteract this, a cooling material, such as cooled aluminum, is temporarily brought into physical contact with the thermally conductive layer of the platen. The heat resident in the platen is transferred to the cold substrate, and the platen is then ready for use. In one embodiment, the cooling material consists of two cooled aluminum pads that are brought into contact with the exposed bottom surface of the platen. The pads are cooled, such as by liquid or gaseous nitrogen, to a temperature of approximately −180° C. A small gas bleed on the surface of the pad improves conduction. The platen sits on the pads until it is at the operating temperature and then the pads move away. The wafer is implanted at the cold temperature and the cooling process is repeated as necessary depending on the heat load of the implants.

While the previous section describes the use of cryogenic implantation, the system and method disclosed herein can also be used for implantations done at room or elevated temperatures as well.

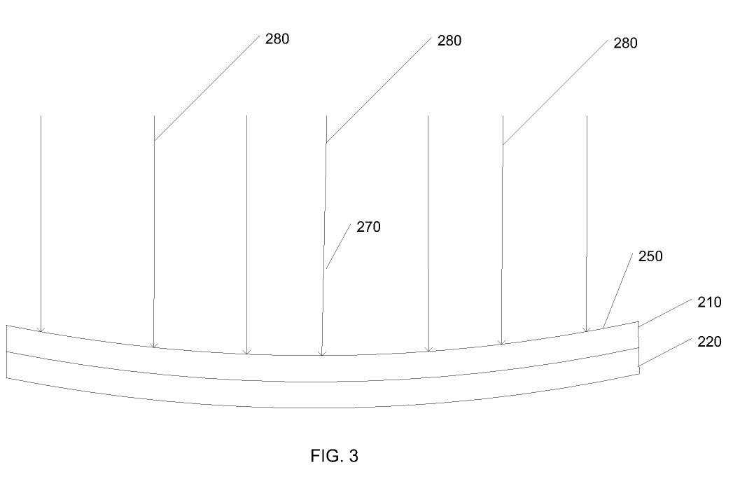

In addition to the benefits of greater temperature operating range, the ESC of the present disclosure also allows the ion implantation system to minimize implant angle variation over the entire work surface 250. Referring to FIG. 3, it can be seen that the implantation angle changes as the beam moves away from the center of the wafer. If the ion beam 280 were assumed to perpendicularly strike the center 270 of the work surface 250, it is clear that the implantation angles at the ends of the work surface are no longer perpendicular. Such deviation becomes more and more important as geometries continue to shrink. The ESC described in the present disclosure is able to more tightly maintain the desired implantation angle, as there is little or no deflection of the chuck as a result of differences in the thermal expansion between the layers.

While this disclosure describes the use of the layered assembly primarily as an electrostatic chuck in ion implantation applications, the disclosure is not limited to only this application. Any semiconductor process requiring a device to hold a wafer in place can utilize this assembly. Furthermore, any application that requires an assembly having two layers having dissimilar CTEs can incorporate the layered assembly disclosed herein.

1. A layered assembly, comprising:
a. A first electrically non-conductive layer, having a first coefficient of thermal expansion;
b. A second thermally conductive layer, bonded to said first layer, comprising a metal and a CTE modifying agent, said second layer having a second coefficient of thermal expansion.

2. The layered assembly of claim 1, whereby said first and second coefficients of thermal expansion are within 100% of one another.

3. The layered assembly of claim 1, whereby said first and second coefficients of thermal expansion are chosen so as to yield an operating range of ±100° C.

4. The layered assembly of claim 1, wherein said first nonconductive layer comprises alumina.

5. The layered assembly of claim 1, wherein said metal in said second layer comprises aluminum.

6. The layered assembly of claim 1, wherein said CTE modifying agent comprises carbon or graphite fiber.

7. The layered assembly of claim 1, wherein said CTE modifying agent comprises silicon.

8. The layered assembly of claim 1, wherein said layered assembly comprises an electrostatic chuck.

9. The layered assembly of claim 1, further comprising:
a. a fluid conduit in said second layer.

10. The layered assembly of claim 9, wherein said first nonconductive layer comprises alumina.

11. The layered assembly of claim 9, wherein said conduit comprises a tube having a higher melting point than said second layer.

12. The layered assembly of claim 11, wherein said tube comprises a material selected from the group consisting of INVAR, molybdenum and stainless steel.

13. The layered assembly of claim 9, wherein said second layer comprises aluminum and graphite or carbon fibers.

14. The layered assembly of claim 9, wherein said assembly comprises an electrostatic chuck.

15. A method of ion implantation of a wafer comprising:
a. Providing an ion implantation system comprising an ion source;
b. Providing an electrostatic chuck, comprising:
i. A first electrically nonconductive layer, having a first coefficient of thermal expansion;
ii. A second thermally conductive layer, bonded to said first layer, having a second coefficient of thermal expansion; and
iii. A fluid conduit in said second layer;
c. Passing a fluid through said conduit to maintain said chuck at a required temperature;
d. Supporting said wafer with said electrostatic chuck; and
e. Implanting ions in said wafer from said ion source.

16. The method of claim 15, wherein said first nonconductive layer comprises alumina.

17. The method of claim 15, wherein said conduit comprises a tube having a higher melting point than said second layer.

18. The method of claim 17, wherein said tube comprises a material selected from the group consisting of INVAR, molybdenum and stainless steel.

19. The method of claim 15, wherein said second layer comprises aluminum and graphite or carbon fibers.

20. The method of claim 15, wherein said fluid comprises nitrogen.

21. The method of claim 15, further comprising maintaining said wafer at a temperature between −100° C. and 100° C.

22. A method of making an electrostatic chuck for supporting a wafer to be implanted with ions, comprising:
a. Determining an operating temperature range for implanting said wafer;
b. Providing a first layer of said chuck for contacting a wafer and supporting it electrostatically; said first layer being electrically non-conductive;
c. Determining the coefficient of thermal expansion of said first layer;
d. Providing a second layer of said chuck, said second layer being thermally conductive;
e. Determining the coefficient of thermal expansion of said second layer;
f. Modifying the coefficient of thermal expansion of said second layer by adding to said second layer a CTE modifying agent in an amount effective for forming a composite second layer having a coefficient of thermal expansion such that said electrostatic chuck is operable over said desired operating temperature range; and
g. Bonding said second composite layer to said first layer.
